(19) United States
(12) Patent Application Publication
(10) Pub. No.: US 2019/0131454 A1
(43) Pub. Date: May 2, 2019

(54) SEMICONDUCTOR DEVICE WITH STRAINED SILICON LAYERS ON POROUS SILICON

(71) Applicant: QUALCOMM Incorporated, San Diego, CA (US)

(72) Inventors: Sinan GOKTEPELI, San Diego, CA (US); Stephen Alan FANELLI, San Marcos, CA (US); Richard HAMMOND, Newport (GB)

(21) Appl. No.: 15/800,916

(22) Filed: Nov. 1, 2017

(51) Int. Cl. H01L 29/78; H01L 27/092; H01L 21/02; H01L 21/762; H01L 21/8238

(52) U.S. Cl. CPC H01L 29/7849; H01L 21/02658; H01L 21/0203; H01L 21/02502; H01L 21/02236; H01L 21/02255; H01L 21/762; H01L 21/0245; H01L 21/02447; H01L 21/02513; H01L 21/02381; H01L 21/02428; H01L 21/02532; H01L 21/823878; H01L 21/02164; H01L 21/02271; H01L 27/092

(57) ABSTRACT

A semiconductor device includes a porous silicon layer on a silicon substrate. A strain inducing intermediate layer (SIIL) is on the porous silicon layer. A silicon layer is on the SIIL. Lattice constant of the silicon layer is different from lattice constant of the SIIL. Thus, the silicon layer is strained. By employing different strain inducing materials in the SIIL, the silicon layer can be used to form different complementary metal oxide semiconductor (CMOS) transistors with improved characteristics.

### BACKGROUND

### Field

Certain aspects of the present disclosure generally relate to integrated circuits (ICs), and more particularly, to semiconductor device with strained silicon layers on porous silicon.

### Background

In the past several decades, semiconductor industry continued to improve the performance of complementary metal oxide semiconductor (CMOS) transistors by scaling down the dimensions of the CMOS transistors. For example, to increase the speed of CMOS transistors, one of the controlling factors is the time of the charge carriers travelling through the channel region under the gate of the transistor. By reducing the gate length, the charge carrier travel time can be shortened to increase the speed of the transistor. However, as the dimension of the gate approaches the physical limitation in miniaturization of CMOS process, it becomes more difficult to further improve the speed of CMOS transistors.

One alternative approach to improve the speed of CMOS transistors employs strained silicon (Si) in the channel region of the transistor. By implementing appropriate strain in silicon, the charge carrier mobility in silicon can be improved, resulting in higher speed of the charge carriers, which can lead to relaxation on the dimension of the gate.

Strained silicon is commonly obtained by growing silicon on Silicon Germanium (SiGe) or Silicon Carbide (SiC). There have been experiments with strained silicon fabricated on dielectric materials. However, cost of fabrication and defectivity remain to be the limiting factors on mass production. The strain in the silicon is introduced by lattice mismatch between Si and SiGe or between Si and SiC. The lattice constant of SiGe is higher than the lattice constant of Si, such that silicon layer grown on SiGe is subject to tensile strain. The lattice constant of SiC is lower than the lattice constant of Si, such that silicon layer grown on SiC is subject to compressive strain. Because electron and hole mobilities respond to mechanical strain in different manners, different strains can be applied to N-type metal oxide semiconductor (NMOS) transistors and P-type metal oxide semiconductor (PMOS) transistors to improve the performance of the transistors. Tensile strain improves electron mobility, which can be used to improve the performance of NMOS transistors. On the other hand, compressive strain improves hole mobility, which can be used to improve the performance of PMOS transistors.

The strain inducing materials, such as SiGe and SiC, are commonly obtained by epitaxial growth on silicon substrate. Because of the lattice mismatch between Si and the strain inducing materials, the strain inducing materials are difficult to grow epitaxially on silicon without defects, such as dislocations, resulting in poor quality of the strain inducing materials, which can affect the quality of the strained silicon grown on them. Thus, there is a need to develop a process to incorporate the strain inducing materials with minimum defects on silicon substrate.

### SUMMARY

Certain aspects of the present disclosure provide a semiconductor device. The semiconductor device may include a porous silicon layer on a silicon substrate. The semiconductor device may also include a strain inducing intermediate layer on the porous silicon layer and a silicon layer on the strain inducing intermediate layer. In certain aspects, a lattice constant of the strain inducing intermediate layer is different from a lattice constant of the silicon layer.

Certain aspects of the present disclosure provide a method for fabricating a semiconductor device. The method may include forming a porous silicon layer on a silicon substrate, forming a seal layer on the porous silicon layer, and forming a strain inducing intermediate layer on the seal layer. The method may also include forming a silicon layer on the strain inducing intermediate layer. In certain aspects, a lattice constant of the strain inducing intermediate layer is different from a lattice constant of the silicon layer.

Certain aspects of the present disclosure provide a method for fabricating a semiconductor device. The method may include forming a porous silicon layer on a silicon substrate and forming a seal layer on the porous silicon layer. The method may also include forming a first oxide layer on the seal layer, patterning the first oxide layer to expose a first portion of the seal layer, and forming a first strain inducing intermediate layer on the first portion of the seal layer. The method may further include forming a second oxide layer on the first strain inducing intermediate layer and the first oxide layer, patterning the first oxide layer and the second oxide layer to expose a second portion of the seal layer, forming a second strain inducing intermediate layer on the second portion of the seal layer, and removing the second oxide layer from the first strain inducing intermediate layer and the first oxide layer. The method may further include forming a first silicon layer on the first strain inducing intermediate layer and a second silicon layer on the second strain inducing intermediate layer. In certain aspects, a lattice constant of the first strain inducing intermediate layer is different from a lattice constant of the first silicon layer and a lattice constant of the second strain inducing intermediate layer is different from a lattice constant of the second silicon layer.

This has outlined, rather broadly, the features and embodiments of the present disclosure in order that the detailed description that follows may be better understood. Additional features and embodiments of the present disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the present disclosure as set forth in the appended claims. The features, which are believed to be characteristic of the present disclosure, both as to its organization and method of operation, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

FIG. 1 is a cross-sectional diagram of an exemplary semiconductor device with strained silicon formed on a silicon substrate with a porous silicon layer in accordance with certain aspects of the present disclosure;

FIG. 2 provides a flow chart illustrating an exemplary fabrication process for the semiconductor device of FIG. 1 in accordance with certain aspects of the present disclosure;

FIGS. 3A-3D are cross-sectional diagrams of the semiconductor device of FIG. 1 at each stage of the process of fabrication in FIG. 2;

FIG. 4 is a cross-sectional diagram of an exemplary semiconductor device with strained silicon formed on a silicon substrate with a porous silicon layer in accordance with certain aspects of the present disclosure;

FIG. 5 provides a flow chart illustrating an exemplary fabrication process for the semiconductor device of FIG. 4 in accordance with certain aspects of the present disclosure;

FIGS. 6A-6F are cross-sectional diagrams of the semiconductor device of FIG. 4 at each stage of the process of fabrication in FIG. 5;

FIG. 7 is a cross-sectional diagram of an exemplary semiconductor device with strained silicon formed on a silicon substrate with a porous silicon layer in accordance with certain aspects of the present disclosure;

FIG. 8 provides a flow chart illustrating an exemplary fabrication process for the semiconductor device of FIG. 7 in accordance with certain aspects of the present disclosure;

FIGS. 9A-9F are cross-sectional diagrams of the semiconductor device of FIG. 7 at each stage of the process of fabrication in FIG. 8; and

FIG. 10 is a block diagram showing an exemplary wireless communication system in which an aspect of the present disclosure may be employed.

### DETAILED DESCRIPTION

With reference to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects. As detailed herein, the term “on” used throughout this description means “directly on” in some configurations, and “indirectly on” in other configurations.

The detailed description set forth below, in connection with the appended drawings, is intended as a description of various configurations and is not intended to represent the only configuration in which the concepts described herein may be practiced. The detailed description includes specific details for the purpose of providing a thorough understanding of the various concepts. It will be apparent to those skilled in the art, however, that these concepts may be practiced without these specific details. In some instances, well-known structures and components are shown in block diagram form in order to avoid obscuring such concepts.

Aspects disclosed in the detailed description include strained silicon formed on a silicon substrate with a porous silicon layer configured to improve the performance of complementary metal oxide semiconductor (CMOS) transistors. In one aspect, a semiconductor device includes a porous silicon layer on a silicon substrate. The semiconductor device also includes a seal layer on the porous silicon layer. Because the seal layer is a thin layer on the porous silicon layer, the seal layer can stretch or compress freely. Thus, the seal layer provides a relaxing surface to form a strain inducing intermediate layer (SIIL) on the seal layer. As a result, the SIIL formed on the seal layer is relaxed, which prevents formation of defects, such as dislocations in the SIIL, even though lattice constant of the SIIL is different from lattice constant of the seal layer. By incorporating the porous silicon layer and the thin seal layer, strain inducing materials in the SIIL can grow with improved quality and lower defect concentrations. The semiconductor device further includes a silicon layer on the SIIL. Lattice constant of the silicon layer is different from the lattice constant of the SIIL. Thus, the silicon layer is strained. With the improved quality and lower defect concentrations of the SIIL, the quality of the silicon layer on the SIIL can be enhanced. By employing different strain inducing materials, the silicon layer can be used to form different CMOS transistors with improved characteristics.

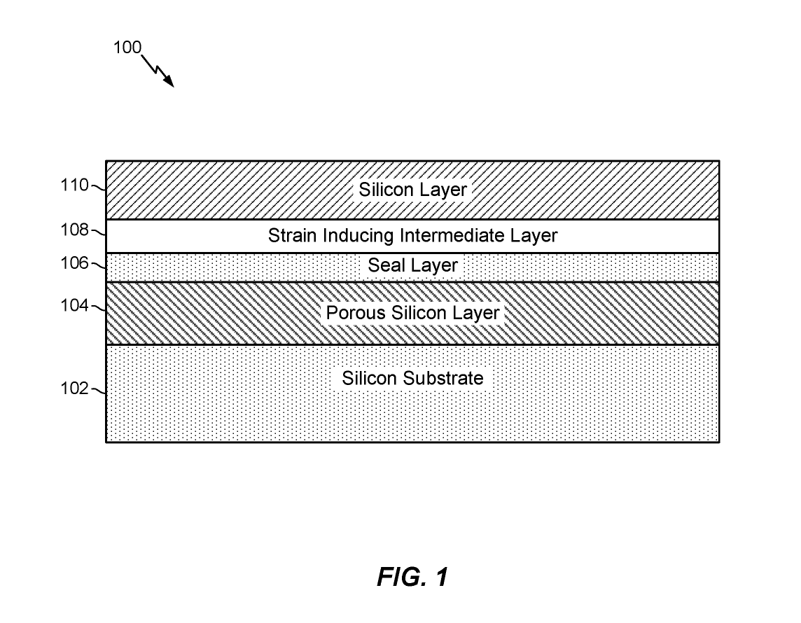

In this regard, FIG. 1 illustrates an exemplary semiconductor device with strained silicon formed on a silicon substrate with a porous silicon layer in accordance with certain aspects of the present disclosure. A semiconductor device 100 is shown in FIG. 1, which includes different layers of materials on a silicon substrate 102. The silicon substrate 102 is a single crystal silicon substrate. A porous silicon layer 104 is on the silicon substrate 102. Porous silicon is a material commonly formed by electrochemical etching of single crystal silicon in solutions containing hydrofluoric acid (HF). Porous silicon is a form of silicon with nanopores or micropores in its structure, resulting in a large surface to volume ratio.

With continuing reference to FIG. 1, a seal layer 106 is on the porous silicon layer 104. The seal layer 106 may be a thin seal layer comprising silicon. The seal layer 106 has a single crystal structure with a uniform surface. As an example, the thickness of the seal layer 106 is in the range of 10 to 30 angstroms. As mentioned above, the seal layer 106 provides a relaxing surface to form an SIIL 108 on the seal layer 106. The SIIL 108 comprises strain inducing materials, such as Silicon Germanium (SiGe) (SiGe may comprise 20%-60% Ge as an example), Silicon Carbide (SiC) (SiC may comprise 0.1%-2% C as an example), in situ doped silicon (e.g., Indium doped silicon and Boron doped silicon), and other in situ doped semiconductor materials. As an example, the thickness of the SIIL 108 is in the range of 100 to 500 angstroms. Because the seal layer 106 is a thin layer on the porous silicon layer 104, the seal layer 106 can stretch or compress freely. As a result, the SIIL 108 formed on the seal layer 106 is relaxed, which prevents formation of defects, such as dislocations in the SIIL 108, even though lattice constant of the SIIL 108 is different from lattice constant of the seal layer 106.

As mentioned in the background, growth of strain inducing materials directly on a silicon substrate will result in poor quality of the strain inducing materials with high defect concentrations. By incorporating the porous silicon layer 104 and the thin seal layer 106, the strain inducing materials in the SIIL 108 are relaxed when they grow on the seal layer 106, resulting in the SIIL 108 with improved quality and lower defect concentrations.

With continuing reference to FIG. 1, a silicon layer 110 is on the SIIL 108. The silicon layer 110 has a lattice constant that is different from the lattice constant of the SIIL 108. Thus, the silicon layer 110 is strained. With the improved quality and lower defect concentrations of the SIIL 108, the quality of the silicon layer 110 on the SIIL 108 can be enhanced as explained above. If the SIIL 108 comprises SiGe, the silicon layer 110 is tensilely strained. If the SIIL 108 comprises SiC, the silicon layer 110 is compressively strained. Tensile strain can improve mobility of electrons and can be used to improve performance of N-type metal oxide semiconductor (NMOS) transistors. Compressive strain can improve mobility of holes and can be used to improve performance of P-type metal oxide semiconductor (PMOS) transistors. By employing different strain inducing materials, the silicon layer 110 can be used to form different CMOS transistors with improved characteristics.

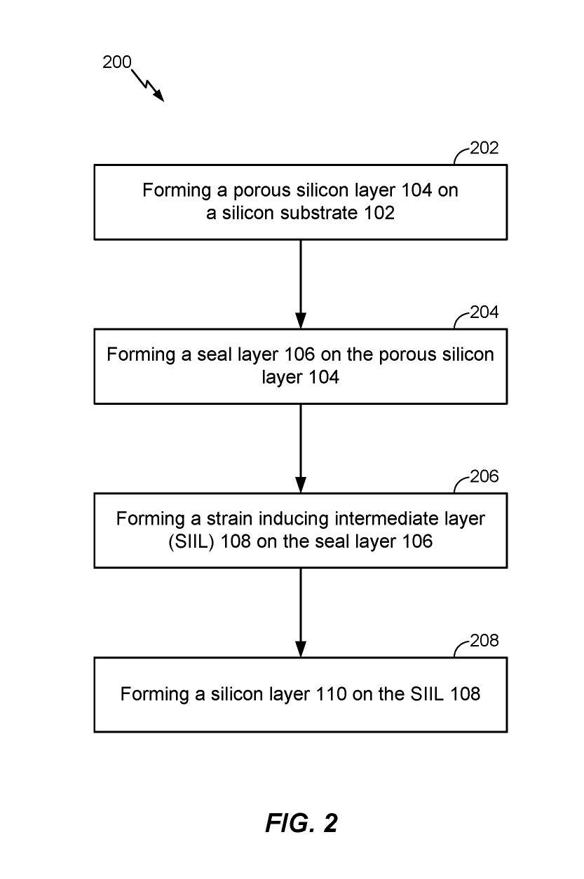

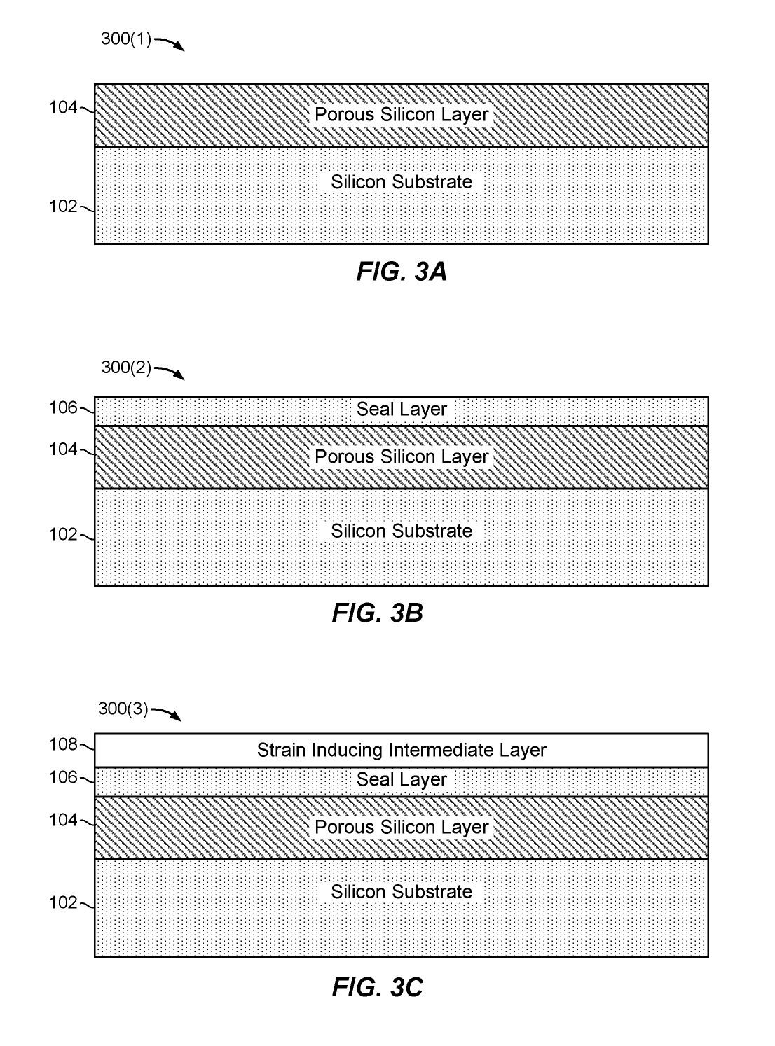

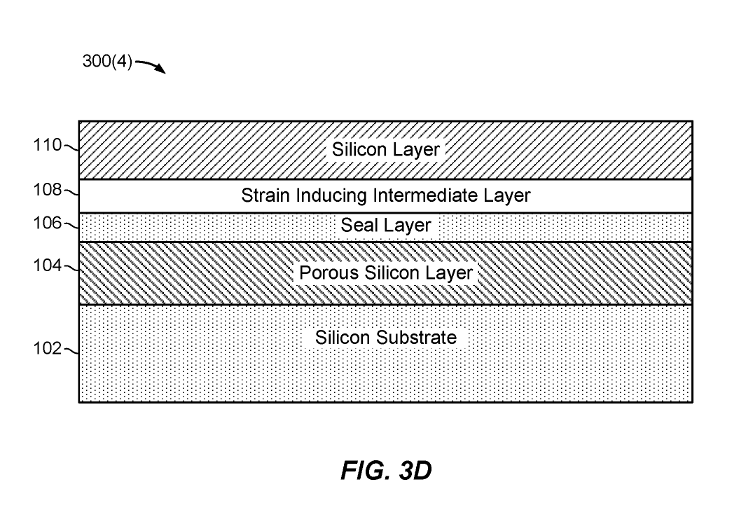

FIG. 2 illustrates an exemplary fabrication process 200 for the semiconductor device 100 in FIG. 1 in accordance with certain aspects of the present disclosure. FIGS. 3A-3D provide cross-sectional diagrams of the semiconductor device 100 of FIG. 1 illustrating respective stages 300(1)-300(4) of the fabrication process 200 in FIG. 2. The cross-sectional diagrams illustrating the semiconductor device 100 in FIGS. 3A-3D will be discussed in conjunction with the discussion of the exemplary steps in the fabrication process 200 in FIG. 2.

In this regard, the fabrication process 200 in FIG. 2 includes forming the porous silicon layer 104 on the single crystal silicon substrate 102 (block 202, stage 300(1) of FIG. 3A). As an example, the porous silicon layer 104 can be obtained by electrochemical etching of the silicon substrate 102 in organic solutions of acetonitrile (CH₃CN) or dimethylformamide (C₃H₇NO) together with HF. An alternative approach is to chemically etch the silicon substrate 102 in mixture of HF and nitric acid (HNO₃) to produce the porous silicon layer 104.

The fabrication process 200 also includes forming the seal layer 106 on the porous silicon layer 104 (block 204, stage 300(2) of FIG. 3B). As an example, the seal layer 106 can be obtained by high temperature annealing of the porous silicon layer 104 in hydrogen (H₂) environment. High temperature annealing in H₂ will close the pores on the porous silicon layer 104 and form a thin single crystal layer (the seal layer 106) with uniform surface. An alternative approach is to perform high temperature oxidation on the porous silicon layer 104. High temperature oxidation will form a thin single crystal layer (the seal layer 106) on the porous silicon layer 104 with an oxide layer on top of the seal layer 106. By removing the oxide layer, the seal layer 106 will be exposed.

The fabrication process 200 further includes forming the SIIL 108 on the seal layer 106 from the strain inducing materials (e.g., SiGe and SiC) (block 206, stage 300(3) of FIG. 3C). As an example, the SIIL 108 can be obtained by epitaxial growth of the strain inducing materials on the seal layer 106. The seal layer 106 is a thin layer on the porous silicon layer 104. Thus, the seal layer 106 can stretch or compress freely. The SIIL 108 formed on the seal layer 106 is relaxed, which prevents formation of defects, such as dislocations in the SIIL 108, and results in the SIIL 108 with improved quality and lower defect concentrations, even though the lattice constant of the SIIL 108 is different from the lattice constant of the seal layer 106.

Next, the fabrication process 200 includes forming the silicon layer 110 on the SIIL 108 (block 208, stage 300(4) of FIG. 3D). As an example, the silicon layer 110 can be obtained by epitaxial growth of silicon on the SIIL 108. As described above, the lattice constant of the silicon layer 110 is different from the lattice constant of the SIIL 108. Thus, the silicon layer 110 formed on the SIIL 108 is strained. With the improved quality and lower defect concentrations of the SIIL 108, the quality of the silicon layer 110 on the SIIL 108 can be enhanced as explained above. If the SIIL 108 comprises SiGe, the silicon layer 110 is tensilely strained. If the SIIL 108 comprises SiC, the silicon layer 110 is compressively strained. The strained silicon layer 110 can be used to improve charge carrier mobility in different CMOS transistors to improve their performance. Following the fabrication process 200, standard CMOS process flow can be used to form various CMOS devices, such as transistors, from the semiconductor device 100.

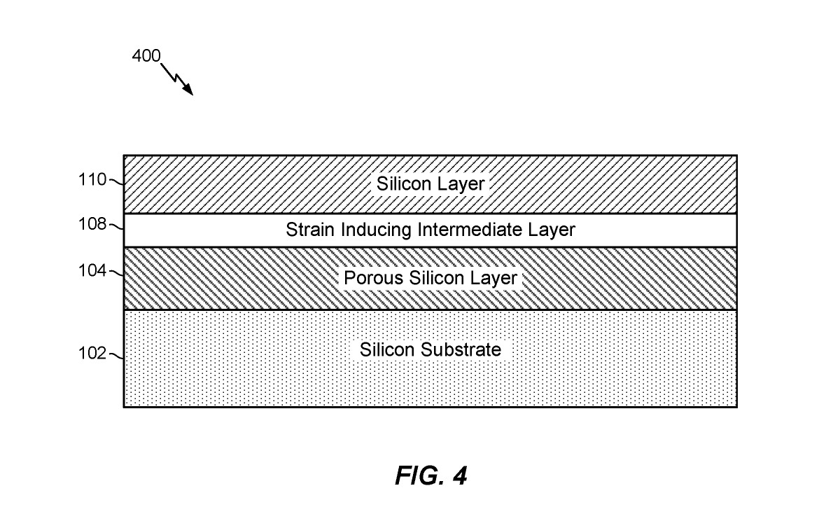

In addition to the semiconductor device 100 described in FIG. 1, FIG. 4 illustrates another exemplary semiconductor device 400 with strained silicon formed on a silicon substrate with a porous silicon layer in accordance with certain aspects of the present disclosure. The semiconductor device 400 includes common elements with the semiconductor device 100 of FIG. 1, which are referred to with common element numbers in FIG. 1 and FIG. 4, and thus will not be re-described herein.

The semiconductor device 400 shown in FIG. 4 includes different layers of materials on a silicon substrate 102. A porous silicon layer 104 is on the silicon substrate 102. An SIIL 108 is on the porous silicon layer 104. A silicon layer 110 is on the SIIL 108. The silicon layer 110 has a lattice constant that is different from lattice constant of the SIIL 108. Thus, the silicon layer 110 is strained. By employing different strain inducing materials in the SIIL 108, the silicon layer 110 can be used to form different CMOS transistors with improved characteristics.

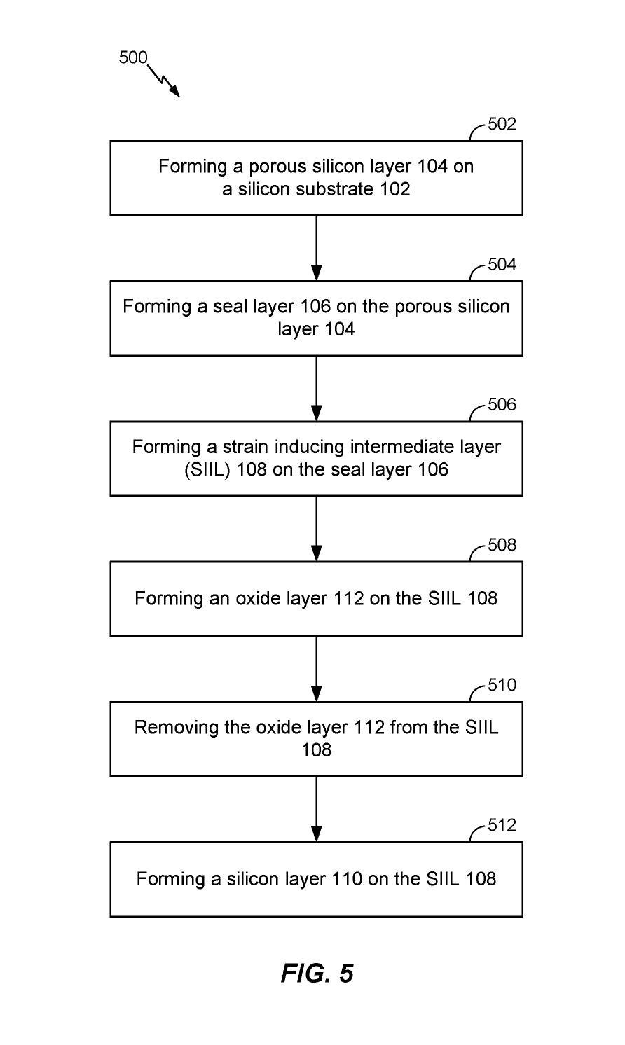

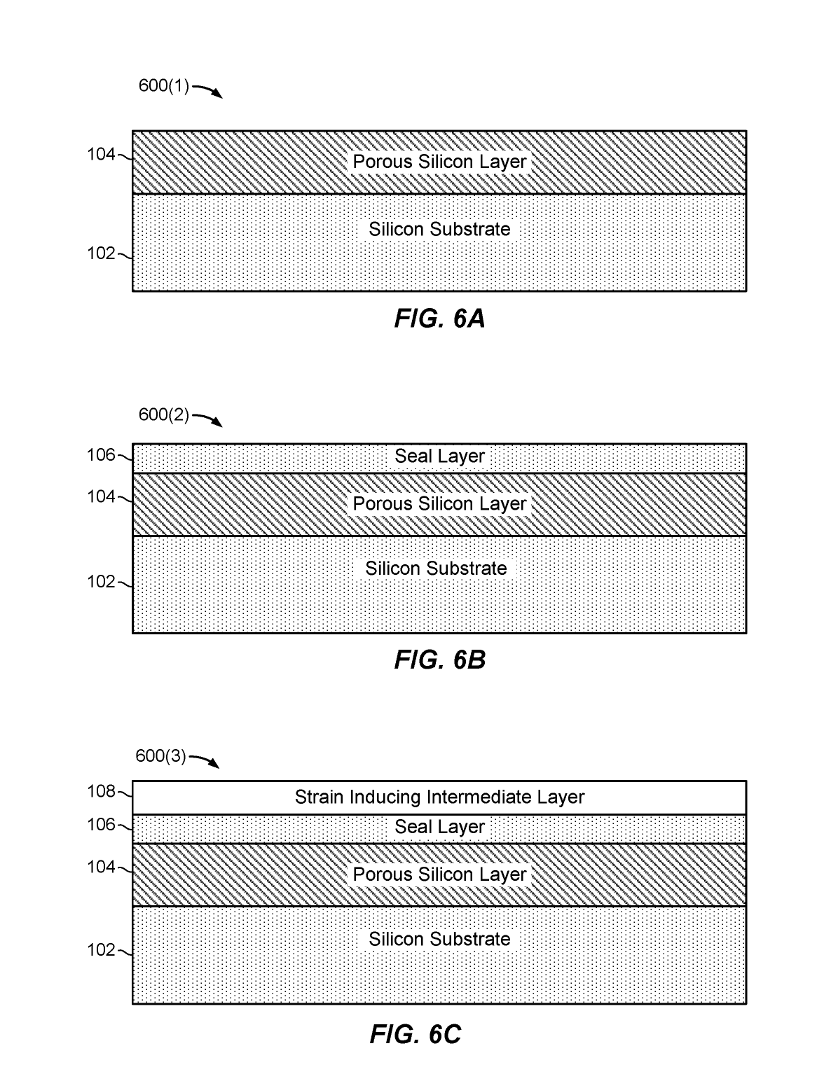

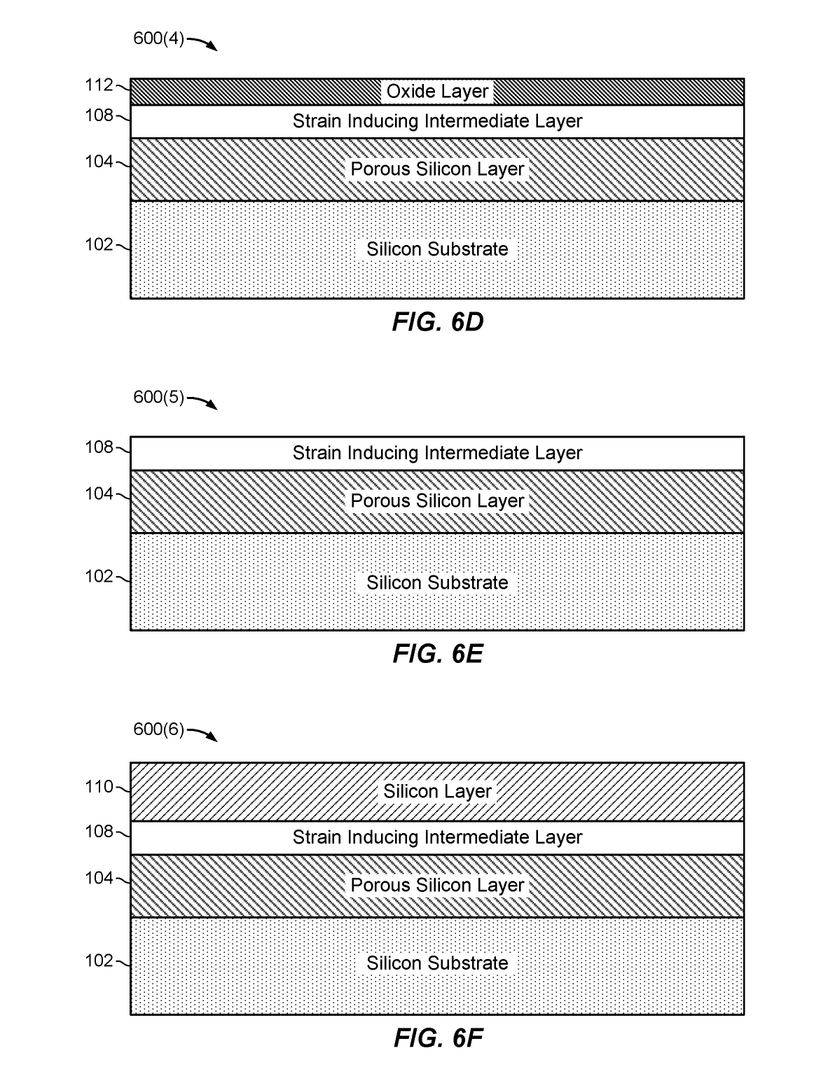

FIG. 5 illustrates an exemplary fabrication process 500 for the semiconductor device 400 in FIG. 4 in accordance with certain aspects of the present disclosure. FIGS. 6A-6F provide cross-sectional diagrams of the semiconductor device 400 of FIG. 4 illustrating respective stages 600(1)-600(6) of the fabrication process 500 in FIG. 5. The cross-sectional diagrams illustrating the semiconductor device 400 in FIGS. 6A-6F will be discussed in conjunction with the discussion of the exemplary steps in the fabrication process 500 in FIG. 5.

In this regard, the fabrication process 500 in FIG. 5 includes forming the porous silicon layer 104 on the single crystal silicon substrate 102 (block 502, stage 600(1) of FIG. 6A). As an example, the porous silicon layer 104 can be obtained by electrochemical etching of the silicon substrate 102 in organic solutions of CH₃CN or C₃H₇NO together with HF. An alternative approach is to chemically etch the silicon substrate 102 in mixture of HF and HNO₃ to produce the porous silicon layer 104.

The fabrication process 500 also includes forming a seal layer 106 on the porous silicon layer 104 (block 504, stage 600(2) of FIG. 6B). As an example, the seal layer 106 can be obtained by high temperature annealing of the porous silicon layer 104 in H₂ environment. High temperature annealing in H₂ will close the pores on the porous silicon layer 104 and form a thin single crystal layer (the seal layer 106) with uniform surface. An alternative approach is to perform high temperature oxidation on the porous silicon layer 104. High temperature oxidation will form a thin single crystal layer (the seal layer 106) on the porous silicon layer 104 with an oxide layer on top of the seal layer 106. By removing the oxide layer, the seal layer 106 will be exposed.

The fabrication process 500 also includes forming the SIIL 108 on the seal layer 106 from the strain inducing materials (e.g., SiGe) (block 506, stage 600(3) of FIG. 6C). As an example, the SIIL 108 can be obtained by epitaxial growth of the strain inducing materials on the seal layer 106. The seal layer 106 is a thin layer on the porous silicon layer 104. Thus, the seal layer 106 can stretch or compress freely. The SIIL 108 formed on the seal layer 106 is relaxed, which prevents formation of defects, such as dislocations in the SIIL 108, and results in the SIIL 108 with improved quality and lower defect concentrations, even though the lattice constant of the SIIL 108 is different from lattice constant of the seal layer 106.

The fabrication process 500 also includes forming an oxide layer 112 on the SIIL 108 (block 508, stage 600(4) of FIG. 6D). As an example, the oxide layer 112 can be obtained by thermal oxidation. During thermal oxidation, the oxide layer 112 (e.g., silicon dioxide (SiO₂)) is formed on the SIIL 108. The oxidation process can snowplow the Ge in the SIIL 108 into the seal layer 106. This process can covert the seal layer 106, which is single crystal silicon, to SiGe with the Ge coming from the SIIL 108. Thus, after thermal oxidation, there is no seal layer 106 remained on the porous silicon layer 104. The SIIL 108 (e.g., SiGe) is directly on the porous silicon layer 104.

The fabrication process 500 further includes removing the oxide layer 112 from the SIIL 108 (block 510, stage 600(5) of FIG. 6E). As an example, the oxide layer 112 can be removed by wet etching or dry etching.

Next, the fabrication process 500 includes forming the silicon layer 110 on the SIIL 108 (block 512, stage 600(6) of FIG. 6F). As an example, the silicon layer 110 can be obtained by epitaxial growth of silicon on the SIIL 108. As described above, the lattice constant of the silicon layer 110 is different from the lattice constant of the SIIL 108. Thus, the silicon layer 110 formed on the SIIL 108 is strained. With the improved quality and lower defect concentrations of the SIIL 108, the quality of the silicon layer 110 on the SIIL 108 can be enhanced as explained above. The strained silicon layer 110 can be used to improve charge carrier mobility in different CMOS transistors to improve their performance. Following the fabrication process 500, standard CMOS process flow can be used to form various CMOS devices, such as transistors, from the semiconductor device 400.

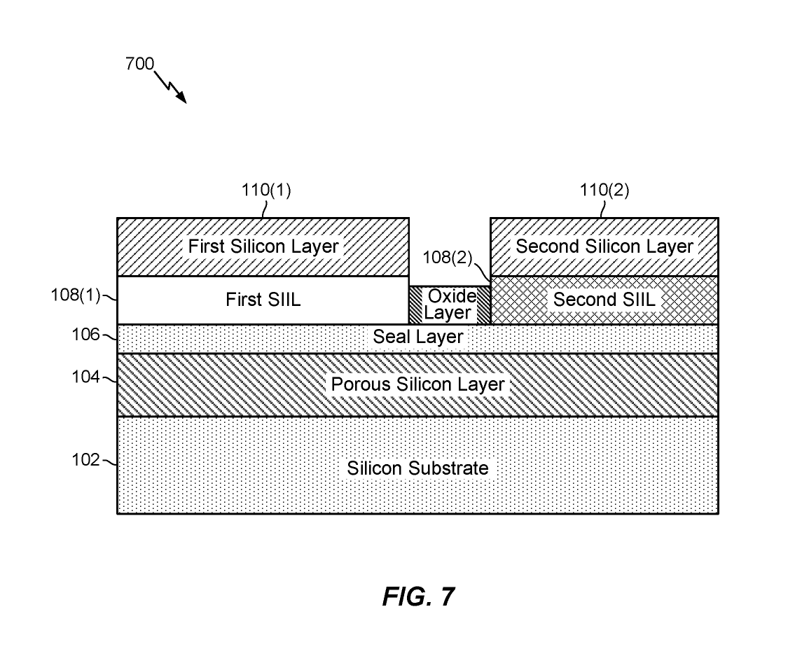

FIG. 7 illustrates another exemplary semiconductor device 700 with strained silicon formed on a silicon substrate with a porous silicon layer in accordance with certain aspects of the present disclosure. The semiconductor device 700 includes common elements with the semiconductor device 100 of FIG. 1 and the semiconductor device 400 of FIG. 4, which are referred to with common element numbers in FIG. 1, FIG. 4, and FIG. 7, and thus will not be re-described herein.

The semiconductor device 700 shown in FIG. 7 includes different layers of materials on a silicon substrate 102. A porous silicon layer 104 is on the silicon substrate 102. A seal layer 106 is on the porous silicon layer 104. A first SIIL 108(1) is on a first portion of the seal layer 106. A second SIIL 108(2) is on a second portion of the seal layer 106. A first silicon layer 110(1) is on the first SIIL 108(1). A second silicon layer 110(2) is on the second SIIL 108(2). The first SIIL 108(1) and the second SIIL 108(2) may comprise same strain inducing materials. Alternatively, the first SIIL 108(1) and the second SIIL 108(2) may comprise different strain inducing materials. An oxide layer may be placed between the first SIIL 108(1) and the second SIIL 108(2) on the seal layer 106 to isolate the first silicon layer 110(1) from the second silicon layer 110(2). Alternatively, other isolation structures, such as shallow trench isolation, may be used between the first SIIL 108(1) and the second SIIL 108(2) to isolate the first silicon layer 110(1) from the second silicon layer 110(2). Lattice constants of the first and second silicon layers are different from lattice constants of the first and second SIILs. Thus, the first and second silicon layers are strained. By employing different strain inducing materials in the first and second SIILs, the first and second silicon layers can be used to form different CMOS transistors with improved characteristics.

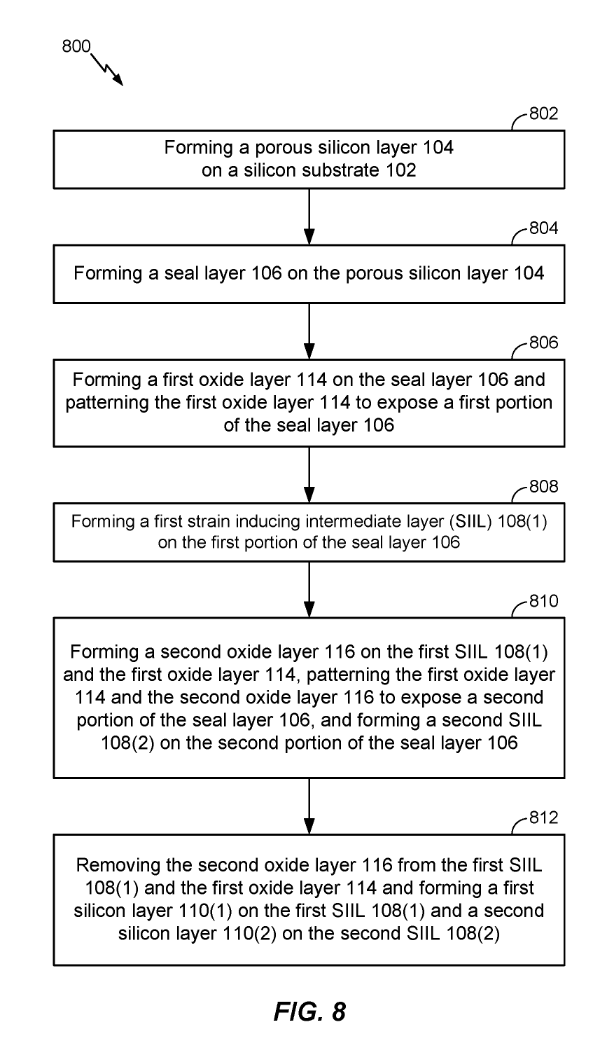

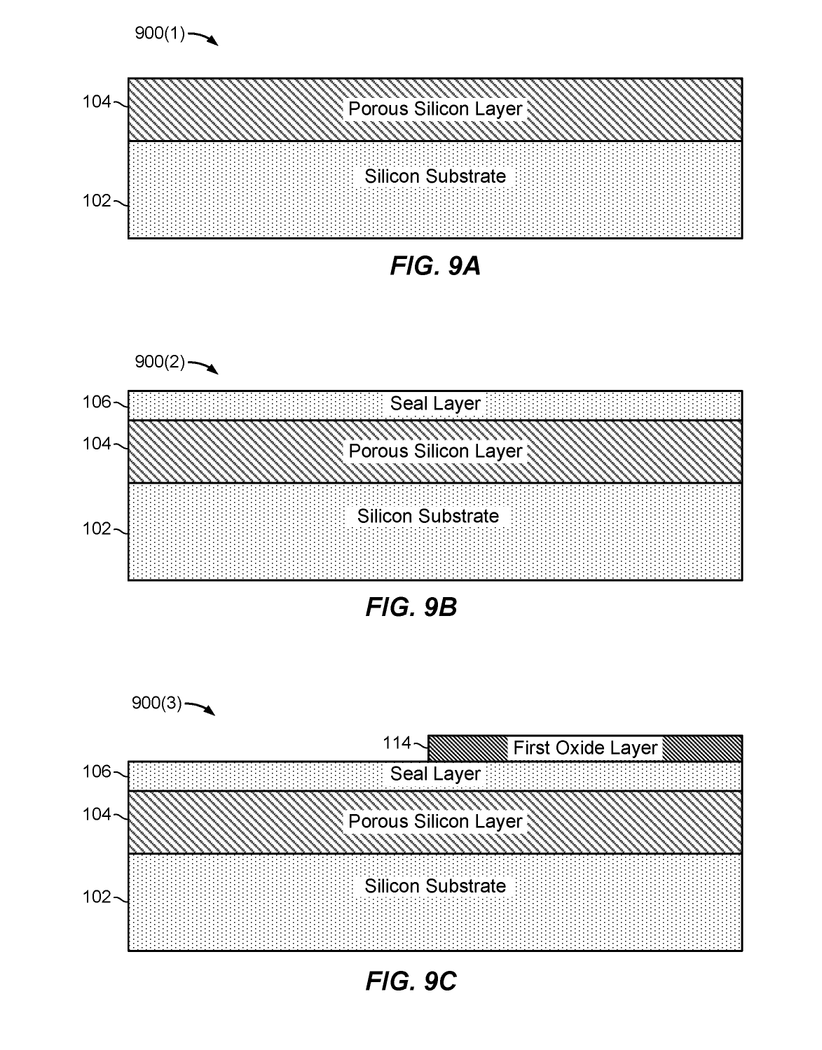

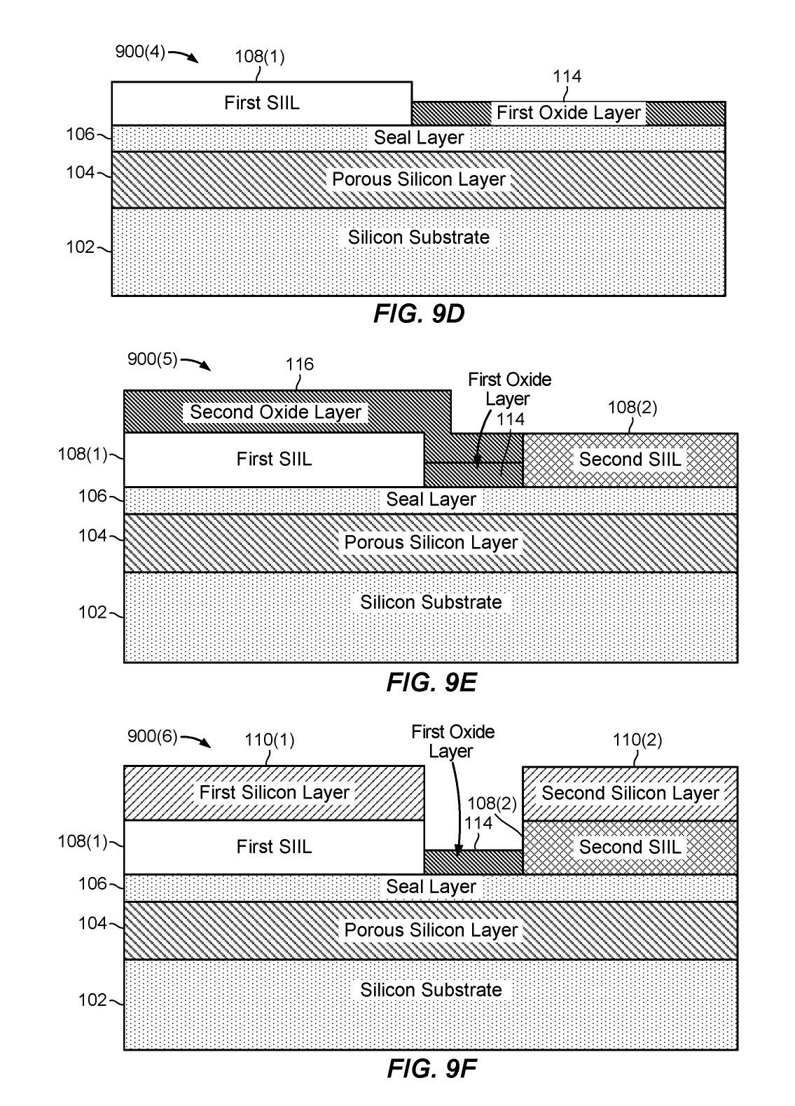

FIG. 8 illustrates an exemplary fabrication process 800 for the semiconductor device 700 in FIG. 7 in accordance with certain aspects of the present disclosure. FIGS. 9A-9F provide cross-sectional diagrams of the semiconductor device 700 of FIG. 7 illustrating respective stages 900(1)-900(6) of the fabrication process 800 in FIG. 8. The cross-sectional diagrams illustrating the semiconductor device 700 in FIGS. 9A-9F will be discussed in conjunction with the discussion of the exemplary steps in the fabrication process 800 in FIG. 8.

In this regard, the fabrication process 800 in FIG. 8 includes forming the porous silicon layer 104 on the single crystal silicon substrate 102 (block 802, stage 900(1) of FIG. 9A). As an example, the porous silicon layer 104 can be obtained by electrochemical etching of the silicon substrate 102 in organic solutions of CH₃CN or C₃H₇NO together with HF. An alternative approach is to chemically etch the silicon substrate 102 in mixture of HF and HNO₃ to produce the porous silicon layer 104.

The fabrication process 800 also includes forming the seal layer 106 on the porous silicon layer 104 (block 804, stage 900(2) of FIG. 9B). As an example, the seal layer 106 can be obtained by high temperature annealing of the porous silicon layer 104 in H₂ environment. High temperature annealing in H₂ will close the pores on the porous silicon layer 104 and form a thin single crystal layer (the seal layer 106) with uniform surface. An alternative approach is to perform high temperature oxidation on the porous silicon layer 104. High temperature oxidation will form a thin single crystal layer (the seal layer 106) on the porous silicon layer 104 with an oxide layer on top of the seal layer 106. By removing the oxide layer, the seal layer 106 will be exposed.

The fabrication process 800 also includes forming a first oxide layer 114 on the seal layer 106 (block 806, stage 900(3) of FIG. 9C). As an example, the first oxide layer 114 can be obtained by chemical vapor deposition, such as plasma enhanced chemical vapor deposition (PECVD). After deposition of the first oxide layer 114, the first oxide layer 114 can be patterned by etching (e.g., wet etching) to expose the first portion of the seal layer 106.

The fabrication process 800 also includes forming the first SIIL 108(1) on the first portion of the seal layer 106 from the strain inducing materials (e.g., SiGe) (block 808, stage 900(4) of FIG. 9D). As an example, the first SIIL 108(1) can be obtained by selective epitaxial growth of the strain inducing materials on the first portion of the seal layer 106. The selective epitaxial growth of the strain inducing materials can prevent the strain inducing materials from growing on the first oxide layer 114. The seal layer 106 is a thin layer on the porous silicon layer 104. Thus, the seal layer 106 can stretch or compress freely. The first SIIL 108(1) formed on the seal layer 106 is relaxed, which prevents formation of defects, such as dislocations in the first SIIL 108(1), and results in the first SIIL 108(1) with improved quality and lower defect concentrations, even though the lattice constant of the first SIIL 108(1) is different from lattice constant of the seal layer 106.

The fabrication process 800 further includes forming a second oxide layer 116 on the first SIIL 108(1) and the first oxide layer 114, patterning the first oxide layer 114 and the second oxide layer 116 to expose the second portion of the seal layer 106, and forming the second SIIL 108(2) on the second portion of the seal layer 106 from the strain inducing materials (e.g., SiC) (block 810, stage 900(5) of FIG. 9E). As an example, the second oxide layer 116 can be obtained on the first SIIL 108(1) and the first oxide layer 114 by chemical vapor deposition, such as PECVD. The first oxide layer 114 and the second oxide layer 116 can be patterned by etching (e.g., wet etching) to expose the second portion of the seal layer 106. The second SIIL 108(2) can be obtained by selective epitaxial growth of the strain inducing materials on the second portion of the seal layer 106. The selective epitaxial growth of the strain inducing materials can prevent the strain inducing materials from growing on the second oxide layer 116. The seal layer 106 is a thin layer on the porous silicon layer 104. Thus, the seal layer 106 can stretch or compress freely. The second SIIL 108(2) formed on the seal layer 106 is relaxed, which prevents formation of defects, such as dislocations in the second SIIL 108(2), and results in the second SIIL 108(2) with improved quality and lower defect concentrations, even though the lattice constant of the second SIIL 108(2) is different from the lattice constant of the seal layer 106.

Next, the fabrication process 800 includes removing the second oxide layer 116 from the first SIIL 108(1) and the first oxide layer 114 and forming the first and second silicon layers on the first and second SIILs (block 812, stage 900(6) of FIG. 9F). As an example, the second oxide layer 116 can be removed from the first SIIL 108(1) and the first oxide layer 114 by wet etching or dry etching. The first and second silicon layers can be obtained by selective epitaxial growth of silicon on the first and second SIILs. The selective epitaxial growth of the first and second silicon layers can prevent silicon from growing on the first oxide layer 114. As described above, the lattice constants of the first and second silicon layers are different from the lattice constants of the first and second SIILs. Thus, the first and second silicon layers formed on the first and second SIILs are strained. With the improved quality and lower defect concentrations of the first and second SIILs, the quality of the first and second silicon layers on the first and second SIILs can be enhanced as explained above. The strained first and second silicon layers can be used to improve charge carrier mobility in different CMOS transistors to improve their performance Following the fabrication process 800, standard CMOS process flow can be used to form various CMOS devices, such as transistors, from the semiconductor device 700.

The elements described herein are sometimes referred to as means for performing particular functions. In this regard, the silicon substrate 102 is sometimes referred to herein as “means for supporting a porous silicon layer.” The seal layer 106 is sometimes referred to herein as “means for sealing a porous silicon layer.” The SIIL 108 is sometimes referred to herein as “means for inducing strain.” According to a further aspect of the present disclosure, the aforementioned means may be any layer, module, or any apparatus configured to perform the functions recited by the aforementioned means.

The semiconductor device with strained silicon formed on a silicon substrate with a porous silicon layer to improve the performance of CMOS transistors according to certain aspects disclosed herein may be provided in or integrated into any electronic device. Examples, without limitation, include a set top box, an entertainment unit, a navigation device, a communication device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, and a drone.

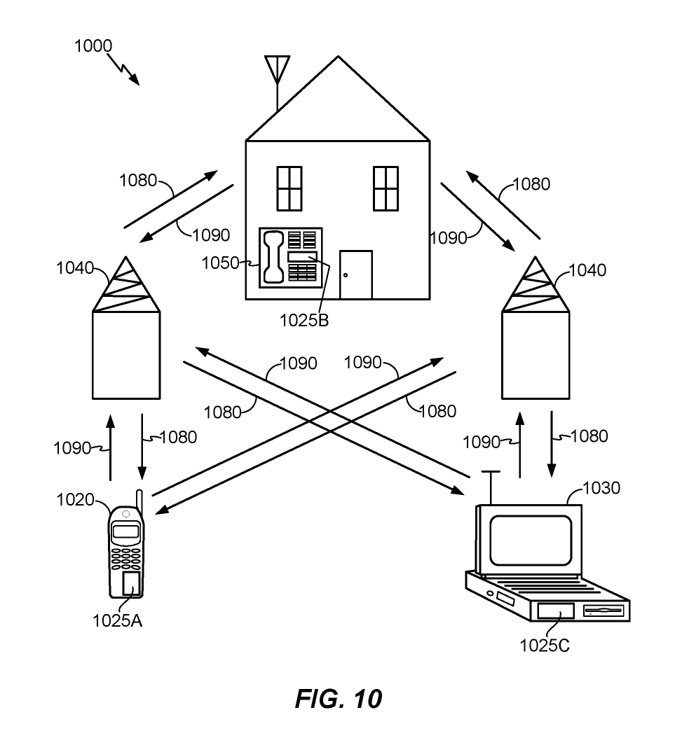

In this regard, FIG. 10 is a block diagram showing an exemplary wireless communication system 1000 in which an aspect of the present disclosure may be employed. For purposes of illustration, FIG. 10 shows three remote units 1020, 1030, and 1050 and two base stations 1040. It will be recognized that wireless communication systems may have many more remote units and base stations. Remote units 1020, 1030, and 1050 include integrated circuit (IC) devices 1025A, 1025C, and 1025B that may include the disclosed semiconductor device. It will be recognized that other devices may also include the disclosed semiconductor device, such as the base stations, switching devices, and network equipment. FIG. 10 shows forward link signals 1080 from the base stations 1040 to the remote units 1020, 1030, and 1050 and reverse link signals 1090 from the remote units 1020, 1030, and 1050 to the base stations 1040.

In FIG. 10, remote unit 1020 is shown as a mobile telephone, remote unit 1030 is shown as a portable computer, and remote unit 1050 is shown as a fixed location remote unit in a wireless local loop system. For example, a remote unit may be a mobile phone, a hand-held personal communication systems (PCS) unit, a portable data unit such as a PDA, a GPS enabled device, a navigation device, a set top box, a music player, a video player, an entertainment unit, a fixed location data unit, such as a meter reading equipment, or other communication device that stores or retrieves data or computer instructions, or combinations thereof. Although FIG. 10 illustrates remote units according to the certain aspects of the present disclosure, the disclosure is not limited to these exemplary illustrated units. Certain aspects of the present disclosure may be suitably employed in many devices, which include the disclosed semiconductor device.

Those of skill in the art will further appreciate that the various illustrative logical blocks, modules, circuits, and algorithms described in connection with the certain aspects disclosed herein may be implemented as electronic hardware, instructions stored in memory or in another computer readable medium and executed by a processor or other processing device, or combinations of both. The devices described herein may be employed in any circuit, hardware component, IC, or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the certain aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and features disclosed herein.

1. A semiconductor device, comprising:
a silicon substrate;
a porous silicon layer on the silicon substrate;
a strain inducing intermediate layer on the porous silicon layer; and
a silicon layer on the strain inducing intermediate layer, wherein a lattice constant of the strain inducing intermediate layer is different from a lattice constant of the silicon layer.

2. The semiconductor device of claim 1, further comprising a seal layer on the porous silicon layer, wherein the strain inducing intermediate layer is on the seal layer.

3. The semiconductor device of claim 2, wherein a lattice constant of the seal layer is different from the lattice constant of the strain inducing intermediate layer.

4. The semiconductor device of claim 2, wherein the seal layer comprises single crystal silicon.

5. The semiconductor device of claim 1, wherein the strain inducing intermediate layer comprises at least one of Silicon Germanium (SiGe), Silicon Carbide (SiC), and doped silicon.

6. The semiconductor device of claim 2, wherein the strain inducing intermediate layer comprises a first strain inducing intermediate layer and a second strain inducing intermediate layer, and wherein the first strain inducing intermediate layer is on a first portion of the seal layer and the second strain inducing intermediate layer is on a second portion of the seal layer.

7. The semiconductor device of claim 6, wherein the silicon layer comprises a first silicon layer and a second silicon layer, wherein the first silicon layer is on the first strain inducing intermediate layer and the second silicon layer is on the second strain inducing intermediate layer, and wherein a lattice constant of the first strain inducing intermediate layer is different from a lattice constant of the first silicon layer and a lattice constant of the second strain inducing intermediate layer is different from a lattice constant of the second silicon layer.

8. The semiconductor device of claim 6, wherein the first strain inducing intermediate layer comprises SiGe and the second strain inducing intermediate layer comprises SiC.

9. The semiconductor device of claim 6, further comprising an oxide layer on the seal layer between the first strain inducing intermediate layer and the second strain inducing intermediate layer.

10. The semiconductor device of claim 1 integrated into a device selected from the group consisting of: a set top box; an entertainment unit; a navigation device; a communication device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; and a drone.

11. A method for fabricating a semiconductor device, comprising:
forming a porous silicon layer on a silicon substrate;
forming a seal layer on the porous silicon layer;
forming a strain inducing intermediate layer on the seal layer; and
forming a silicon layer on the strain inducing intermediate layer, wherein a lattice constant of the strain inducing intermediate layer is different from a lattice constant of the silicon layer.

12. The method of claim 11, wherein the forming the porous silicon layer on the silicon substrate comprises electrochemical etching of the silicon substrate.

13. The method of claim 11, wherein the forming the seal layer on the porous silicon layer comprises annealing the porous silicon layer in hydrogen.

14. The method of claim 11, wherein the forming the seal layer on the porous silicon layer comprises performing high temperature oxidation on the porous silicon layer and removing an oxide layer to expose the seal layer.

15. The method of claim 11, wherein the forming the strain inducing intermediate layer on the seal layer comprises epitaxial growth of the strain inducing intermediate layer on the seal layer.

16. The method of claim 11, wherein the forming the silicon layer on the strain inducing intermediate layer comprises epitaxial growth of the silicon layer on the strain inducing intermediate layer.

17. The method of claim 11, wherein a lattice constant of the seal layer is different from the lattice constant of the strain inducing intermediate layer.

18. The method of claim 11, wherein the seal layer comprises single crystal silicon.

19. The method of claim 11, wherein the strain inducing intermediate layer comprises at least one of Silicon Germanium (SiGe), Silicon Carbide (SiC), and doped silicon.

20. The method of claim 11, further comprising forming an oxide layer on the strain inducing intermediate layer and removing the oxide layer before forming the silicon layer on the strain inducing intermediate layer.

21. The method of claim 20, wherein the forming the oxide layer on the strain inducing intermediate layer comprises forming the oxide layer on the strain inducing intermediate layer by thermal oxidation.

22. A method for fabricating a semiconductor device, comprising:
forming a porous silicon layer on a silicon substrate;
forming a seal layer on the porous silicon layer;
forming a first oxide layer on the seal layer;
patterning the first oxide layer to expose a first portion of the seal layer;
forming a first strain inducing intermediate layer on the first portion of the seal layer;
forming a second oxide layer on the first strain inducing intermediate layer and the first oxide layer;
patterning the first oxide layer and the second oxide layer to expose a second portion of the seal layer;
forming a second strain inducing intermediate layer on the second portion of the seal layer;
removing the second oxide layer from the first strain inducing intermediate layer and the first oxide layer; and
forming a first silicon layer on the first strain inducing intermediate layer and a second silicon layer on the second strain inducing intermediate layer, wherein a lattice constant of the first strain inducing intermediate layer is different from a lattice constant of the first silicon layer and a lattice constant of the second strain inducing intermediate layer is different from a lattice constant of the second silicon layer.

23. The method of claim 22, wherein the forming the porous silicon layer on the silicon substrate comprises electrochemical etching of the silicon substrate.

24. The method of claim 22, wherein the forming the seal layer on the porous silicon layer comprises annealing the porous silicon layer in hydrogen.

25. The method of claim 22, wherein the forming the seal layer on the porous silicon layer comprises performing high temperature oxidation on the porous silicon layer and removing an oxide layer to expose the seal layer.

26. The method of claim 22, wherein the forming the first strain inducing intermediate layer on the first portion of the seal layer comprises selective epitaxial growth of the first strain inducing intermediate layer on the first portion of the seal layer.

27. The method of claim 22, wherein the forming the first silicon layer on the first strain inducing intermediate layer comprises selective epitaxial growth of the first silicon layer on the first strain inducing intermediate layer.

28. The method of claim 22, wherein a lattice constant of the seal layer is different from the lattice constant of the first strain inducing intermediate layer and the lattice constant of the second strain inducing intermediate layer.

29. The method of claim 22, wherein the first strain inducing intermediate layer comprises Silicon Germanium (SiGe) and the second strain inducing intermediate layer comprises Silicon Carbide (SiC).

30. The method of claim 22, wherein the forming the first oxide layer on the seal layer comprises depositing the first oxide layer on the seal layer by chemical vapor deposition (CVD).
